(19) United States
(12) Patent Application Publication
(10) Pub. No.: US 2024/0017923 A1
(43) Pub. Date: Jan. 18, 2024

(54) ARTICLE STORAGE SYSTEM

(71) Applicant: SEMES CO., LTD., Cheonan-si (KR)

(72) Inventors: Jong Wan LIM, Hwaseong-si (KR); Young Woo KIM, Cheonan-si (KR); Jun Cheol PARK, Suwon-si (KR)

(73) Assignee: SEMES CO., LTD., Cheonan-si (KR)

(21) Appl. No.: 18/108,651

(22) Filed: Feb. 12, 2023

(30) Foreign Application Priority Data
Jul. 15, 2022 (KR) 10-2022-0087517

(51) Int. Cl. B65G 1/10; B65G 1/137

(52) U.S. Cl. CPC B65G 1/10; B65G 1/137; B65G 2203/0283; B65G 2203/042

(57) ABSTRACT

Proposed is a transport facility for transporting objects, an article storage system including the same, and a method for seating objects in the article storage system.

### CROSS REFERENCE TO RELATED APPLICATION

The present application claims priority to Korean Patent Application No. 10-2022-0087517, filed Jul. 15, 2022, the entire contents of which is incorporated by reference herein for all purposes.

### BACKGROUND OF THE INVENTION

### 1. Field of the Invention

The present disclosure relates to a carrier transport facility for transporting a carrier, an article storage system including the same, and a carrier seating method using the same.

### 2. Description of the Related Art

In general, semiconductor processing apparatuses for manufacturing semiconductor devices are continuously arranged to perform various processes on semiconductor substrates. Objects (articles) on which a semiconductor device manufacturing process is performed may be supplied to or retrieved from each semiconductor processing apparatus in a state of being housed in a carrier (container). Examples of the carrier for storing the objects include a front open unified POD (FOUP), a front opening shipping box (FOSB), a magazine, and a reticle pod.

The carrier may be transported by a vehicle of an overhead hoist transport (OHT). The vehicle may grip a carrier containing objects and transport the carrier to a load port of the semiconductor processing apparatus, and may pick up a carrier in which objects having been processed is stored from the load port and transport the carrier to the outside.

Carriers may be vertically transported by a transport device such as a tower lift, and may be stacked and stored on shelves in a storage device such as a stocker. At this time, the carriers may be transported to the load port of the apparatus by the vehicle, but may also be transported by a user.

### SUMMARY OF THE INVENTION

Accordingly, the present disclosure has been made keeping in mind the above problems occurring in the related art, and the present disclosure is intended to provide an article storage system that prevents abnormal seating of objects done by an operator and guides proper seating of objects.

Objectives of the present disclosure are not limited thereto, and other objectives not mentioned will be clearly understood by those skilled in the art from the following description.

In order to achieve the above objective, according to an embodiment of the present disclosure, there is provided a carrier transport facility, including: a stage provided with a seating surface on which a carrier containing articles is seated; a transport module configured to move up and down through a passage hole formed on the seating surface of the stage and transport the carrier by supporting a lower surface of the carrier; and a controller configured to control the transport module, wherein positioning pins corresponding to positioning grooves provided on the lower surface of the carrier may be provided on an upper surface of the transport module, and the controller may control the transport module to rise to a height of the seating surface of the stage and stand by before the carrier is seated on the seating surface of the stage, so that when the carrier is seated, the positioning grooves provided on the lower surface of the carrier and the positioning pins provided on the upper surface of the transport module may fit to each other to achieve a positioning of the carrier.

According to an embodiment of the present disclosure, there is provided an article storage system, including: a carrier transport unit configured to transport a carrier in which an article is stored; and a storage unit configured to have a plurality of shelves for loading the carrier. The carrier transport unit may include: a load port configured to include a stage provided with a seating surface on which the carrier is seated; a transport module configured to move up and down through a passage hole famed on the seating surface of the stage and transport the carrier by supporting a lower surface of the carrier; and a controller configured to control the transport module, wherein positioning pins corresponding to positioning grooves provided on the lower surface of the carrier may be provided on an upper surface of the transport module, and the controller may control the transport module to rise to a height of the seating surface of the stage and stand by before the carrier is seated on the seating surface of the stage, so that when the carrier is seated, the positioning grooves provided on the lower surface of the carrier and the positioning pins provided on the upper surface of the transport module may fit to each other to achieve a positioning of the carrier.

According to an embodiment of the present disclosure, there is provided a method for seating a carrier in an article storage system, which is a method for properly seating the carrier on a stage provided with a seating surface on which the carrier containing an article is seated, the method including: a first step of locating a transport module for moving up and down through a passage hole formed on the seating surface of the stage and transporting the carrier by supporting a lower surface of the carrier at a same height as the seating surface; a second step of seating the carrier on the stage; and a third step of transporting the carrier by the transport module.

In the embodiment, the method for seating a carrier in an article storage system may further include: a fourth step of storing the carrier transported in the third step.

As described above, according to the present disclosure, it is possible to prevent delivery delays caused by abnormal seating of objects by making an operator immediately recognize abnormal seating of an article so that the object can be properly seated. Particularly, the present disclosure is cost-effective because the accuracy of object placement in an article storage system can be increased without additional hardware design and manufacturing costs since it is possible to guide the seating of objects by simply changing drive logic of existing components.

In addition, according to the present disclosure, it is possible to normalize a seating state of objects within a shorter time since the overall seating state of objects is checked with a plurality of sensors provided on a stage and an alarm is generated in case of abnormal seating of an object.

Furthermore, by applying the article storage system of the present disclosure to a manual port where a carrier is manually seated by an operator, it is possible to prevent abnormal seating of objects done by the operator.

Effects of the present disclosure are not limited thereto, and other effects not mentioned will be clearly understood by those skilled in the art from this specification and the accompanying drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic front view showing an article storage system according to an embodiment of the present disclosure;

FIG. 2 is a schematic plan view showing an article storage system according to the embodiment of the present disclosure;

FIG. 3 is an enlarged view for explaining a part of a carrier transport unit shown in FIGS. 1 and 2;

FIG. 4 shows another example of the part of the carrier transport unit shown in FIG. 3;

FIG. 5 is a side view showing a transport module in a standby state to which the present disclosure is applied;

FIG. 6 is an exploded side view of FIG. 5 for better understanding of the drawing;

FIG. 7 is a configuration diagram showing the configuration of a controller;

FIG. 8 is a schematic flowchart of a method for seating a carrier in an article storage system according to an embodiment of the present disclosure; and

FIG. 9 is a flowchart schematically showing the second step of FIG. 8.

### DETAILED DESCRIPTION OF THE INVENTION

Hereinafter, embodiments of the present disclosure will be described with reference to the accompanying drawings. The present disclosure may be embodied in many different forms and is not limited to the embodiments set forth herein. In each of the drawings described below, directions in the drawings are described using an XYZ coordinate system. In the XYZ coordinate system, a vertical direction (direction of gravity) is the Z direction, and a horizontal direction is the X direction and the Y direction.

In order to clearly describe the present disclosure, detailed descriptions of parts irrelevant to the essence of the present disclosure may be omitted. The same reference numerals may be assigned to the same or similar components throughout the specification.

In addition, in the drawings referred to, the size of components, the thickness of lines, etc. may be expressed somewhat exaggerated or reduced for convenience of understanding.

Furthermore, when a part is said to “comprise”, “have”, or “include” a certain component, it means that it may further include other components, not excluding other components unless otherwise stated. Terms used herein are intended to refer only to specific embodiments and are not intended to limit the present disclosure, and may be interpreted as concepts understood by those of ordinary skill in the art to which the present disclosure pertains unless otherwise defined herein.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed in ideal or excessively formal meanings unless expressly defined in this application.

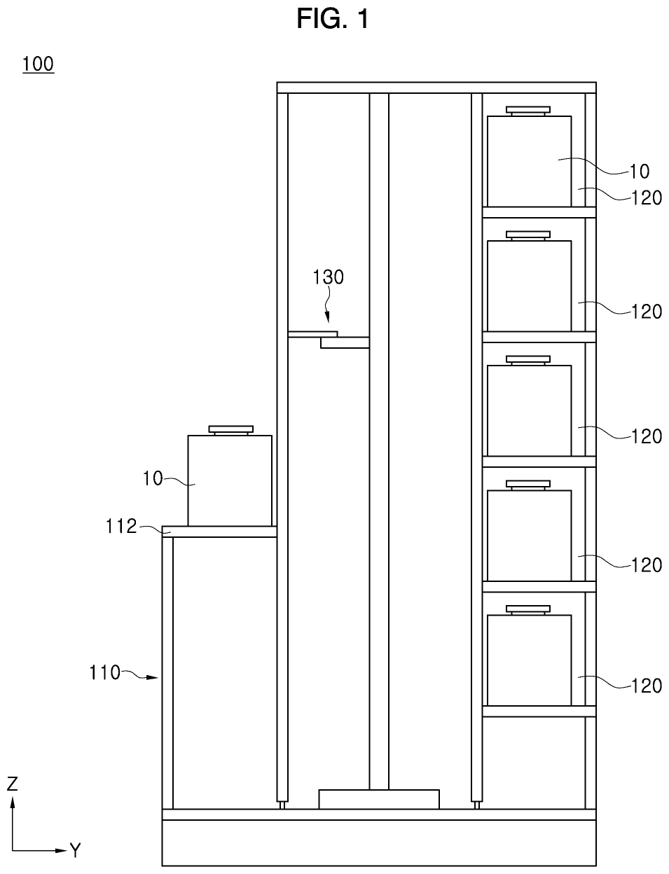

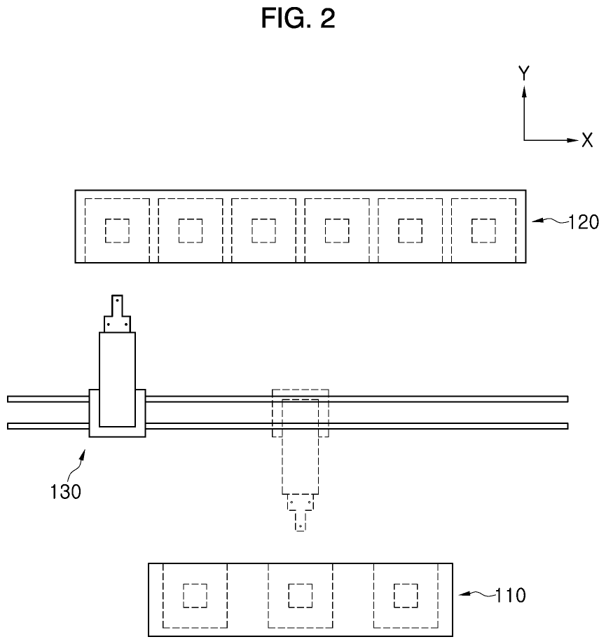

FIGS. 1 and 2 show an article storage system 100 according to an embodiment of the present disclosure. The article storage system 100 according to the embodiment of the present disclosure may include: a carrier transport unit and a storage unit. The article storage system 100 according to the embodiment of the present disclosure may transport and store various types of carriers. For example, the article storage system 100 may include one or more of a multi-stocker, a combo stocker, and a FOUP & POD parallel transport tower lifter.

The carrier transport unit may include a carrier transport facility, and the carrier transport facility may include a load port 110 and a transport module 130.

The load port 110 provides a space in which a carrier 10 containing articles is seated, and loads or unloads the carrier 10. The load port 110 is for delivering the carrier 10 from the outside of the article storage system 100 to the inside space of the article storage system 100, or from the inside space of the article storage system 100 to the outside of the article storage system 100. A plurality of load ports 110 may be provided. One or more positioning grooves 220 may be provided on the lower surface of the carrier 10.

The carrier 10 may be a front open unified POD (FOUP), a front opening shipping box (FOSB), a multi-application carrier, a magazine, a POD, or a reticle pod. The article may be a semiconductor substrate, printed circuit board, reticle, or the like.

Although not shown in detail, the load port 110 may include: a OHT lot port that receives the carrier 10 transported from an overhead hoist transfer (OHT) and delivers the carrier 10 to the inside of the article storage system 100 or delivers the carrier 10 inside the article storage system 100 to the OHT; and a manual load port that delivers the carrier 10 manually seated by a user to the inside of the article storage system 100 or delivers the carrier 10 inside the article storage system 100 to be given to the user to the outside.

Articles used in the semiconductor manufacturing process, such as a plurality of wafers or reticles, may be placed on a seating surface of a stage 112 of the load port 110 while being accommodated in the carrier 10.

The transport module 130 is configured to transport the carrier 10 seated on the stage 112 by supporting the lower surface of the carrier 10, and may lift the carrier 10 seated on the stage 112 from the stage 112 and transport it into the article storage system 100. The transport module 130 may deliver the carrier 10 to the storage unit.

The storage unit may include a plurality of shelves 120 for loading the carrier 10. The shelf 120 may be arranged in a horizontal direction (X-axis direction, Y-axis direction) and a vertical direction (Z-axis direction). For example, a plurality of rows and columns may be arranged side by side in a horizontal direction, and a plurality of stages may be arranged side by side in a vertical direction. Alignment pins (not shown) may be provided on the bottom surface of each shelf 120. When the carrier 10 is loaded on the shelf 120, the alignment pins (not shown) of the shelf 120 are inserted into the positioning grooves 220 of the carrier 10, so that the carrier 10 may be accurately loaded on each shelf 120.

Although not shown in detail, a transport module for transporting the carrier 10 in the storage unit may be provided inside the storage unit. The transport module may transport the carrier 10 in each of the X, Y, and Z directions, and may be provided to transport or deliver carrier 10 between the load port 110 and the shelf 120 and/or from one shelf 120 to another shelf 120. As an example, the transport module may be provided to enable movement and rotation in the X-axis direction and the Z-axis direction for transport of the carrier 10.

Hereinafter, the stage of the present disclosure will be described as being included in a manual port configured to allow a user to manually seat a carrier as an example, but it is not intended to be limited thereto.

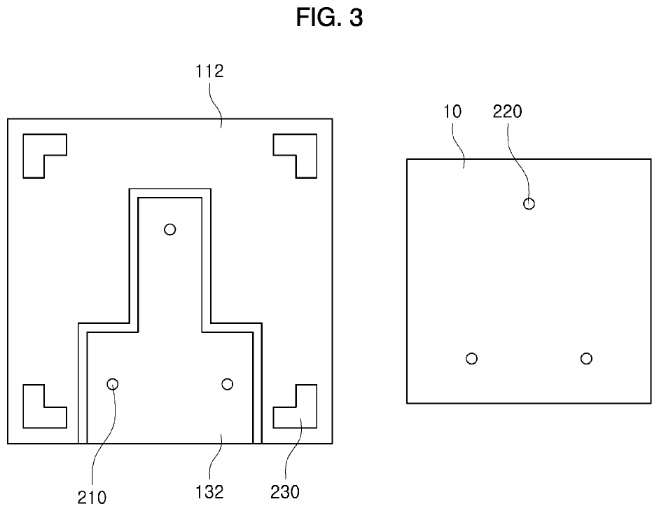

FIG. 3 is an enlarged view showing some configurations of the carrier transport unit shown in FIGS. 1 and 2.

Referring to FIG. 3, the transport module 130 according to the embodiment of the present disclosure includes a saddle-shaped hand 132 for supporting the lower surface of the carrier 10, and on the upper surface of the hand 132, positioning pins 210 corresponding to the positioning grooves 220 provided on the lower surface of the carrier are provided.

The stage 112 includes a saddle-shaped passage hole and a plurality of guide members 230. As an example, the plurality of guide members 230 are configured to guide the correct position of the carrier and may be disposed at positions corresponding to the four vertices of the lower surface of the carrier 10.

That is, the hand 132 may have the same shape as the shape of the passage hole formed on the seating surface of the stage 112, and be provided to be smaller than the passage hole so as to be lifted through the passage hole. Although not shown in detail, the transport module 130 may further include a drive unit (not shown) for lifting and moving the hand 132 through the passage hole of the stage 112.

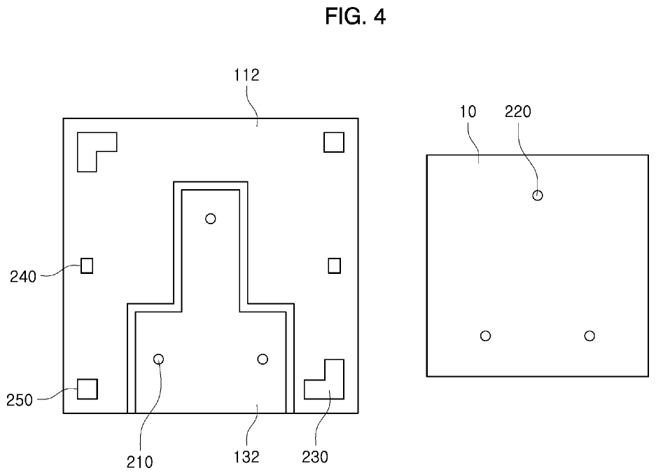

Meanwhile, the stage 112 may further include a first sensor 240 and a second sensor 250 as shown in FIG. 4.

The first sensor 240 is provided in each of the two facing corner areas among the four corner areas of the upper surface of the stage 112, and may be provided with a sensor capable of detecting the presence or absence of the carrier 10.

The second sensor 250 is provided at each of the two facing vertices among the four vertices of the stage 112 to sense the alignment state of the carrier 10. That is, the second sensor 250 may replace the two guide members 230. As an example, the second sensor 250 may include a light receiving unit and a light emitting unit. When the light emitted from the light emitting unit is received by the light receiving unit, it is determined that the carrier 10 seated on the stage 112 is not inclined and is in a horizontal state. On the contrary, when the light emitted from the light emitting unit is not received by the light receiving unit, it is determined that the carrier 10 seated on the stage 112 is inclined.

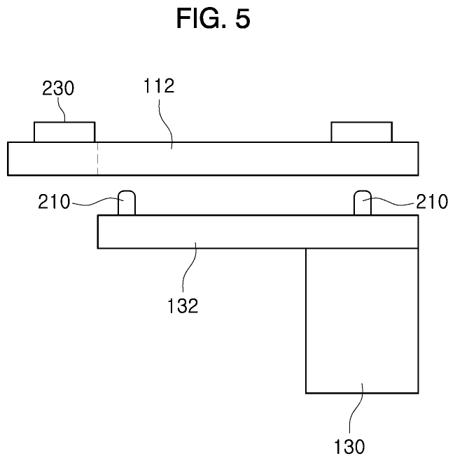

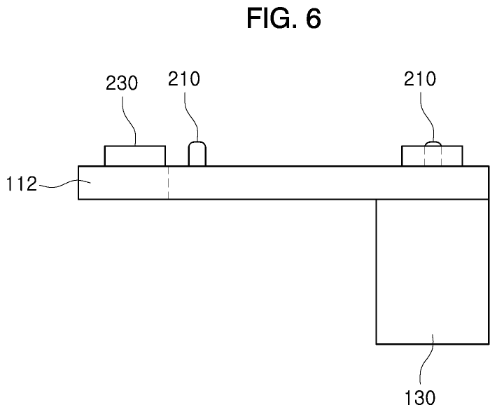

FIG. 5 shows the stage 112 and the transport module 130 before the carrier 10 is seated on the seating surface of the stage 112, and FIG. 6 shows a state in which the stage 112 and the transport module 130 of FIG. 5 are separated for better understanding of the drawing.

As shown in FIG. 5, the transport module 130 of the present disclosure waits in a state located at the same height as the seating surface of the stage 112 before the carrier 10 is seated on the seating surface of the stage 112. Accordingly, when the carrier 10 is properly seated on the seating surface, the positioning grooves 220 provided on the lower surface of the carrier 10 and the positioning pins 210 provided on the upper surface of the transport module 130 fit to each other, so that the positioning of the carrier 10 may be achieved (i.e., the carrier 10 is properly attached to the transport module 130 for transport). For example, when the carrier 10 properly seats on the seating surface, the positioning grooves 220 and the positioning pins 210 are engaged with each other, thereby attaching the carrier 10 to the transport module 130 or securing proper placing of the carrier 10 on the transport module 130 for delivery of the carrier 10.

The carrier transport unit may further include a controller 150 for controlling the above.

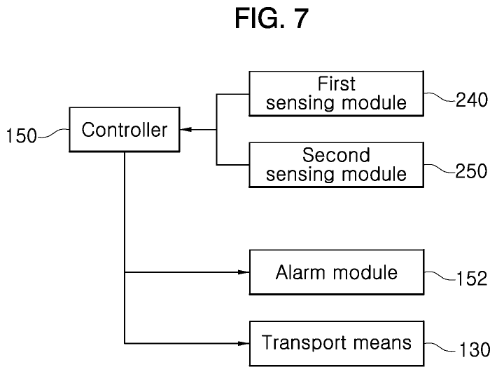

FIG. 7 is a configuration diagram showing the configuration of the controller 150.

The controller 150 may control the transport module 130 to rise to the height of the seating surface and stand by before the carrier 10 is seated on the seating surface of the stage 112 so that the transport module 130 stands by while the upper surface of the transport module 130, that is, the upper surface of the hand 132 and the seating surface of the stage 112 are located at the same height. Accordingly, the controller 150 may control the positioning of the carrier 10 by fitting the positioning grooves 220 provided on the lower surface of the carrier 10 and the positioning pins 210 provided on the upper surface of the hand 132 to each other when the carrier 10 is seated on the seating surface of the stage 112.

The controller 150 may include an alarm module 152.

The alarm module 152 may generate an alarm in case the positioning grooves 220 provided on the lower surface of the carrier and the positioning pins 210 provided on the upper surface of transport module 130 do not fit to each other when the carrier 10 is seated on the seating surface of the stage 112. This is to inform an operator of abnormal seating of the carrier 10 by generating the alarm since the case where the positioning grooves 220 provided on the lower surface of the carrier 10 and the positioning pins 210 provided on the upper surface of transport module 130 do not fit to each other module the abnormal seating of the carrier 10. By making the operator immediately aware of the abnormal seating of the carrier, it is possible to induce proper seating of the carrier 10 and prevent a delivery delay caused by not recognizing the abnormal seating of the carrier 10.

By applying this to a manual port where a carrier is manually seated by a user (operator), it is possible to prevent abnormal seating of articles by the operator and guide the proper seating of the articles.

In addition, the controller 150 may receive detection results from the first sensor 240 and the second sensor 250. The controller 150 may control the alarm module 152 on the basis of the detection results received from the first sensor 240 and the second sensor 250.

The alarm module 152 may generate an alarm when the presence of the carrier 10 is not detected by the first sensor 240 or the alignment of the carrier 10 detected by the second sensor 250 is not horizontal. That is, the alarm module 152 may generate the alarm when it is determined that the seated state of the carrier 10 detected by the first sensor 240 and the second sensor 250 is abnormal. At this time, the alarm module 152 may be controlled to generate the alarm when at least one detection result detected by the first sensor 240 and the second sensor 250 is abnormal.

Meanwhile, although not shown in detail, the carrier transport unit may be provided in the form of a tower lift further including a housing for accommodating the transport module 130 and a rail unit for horizontally moving the housing.

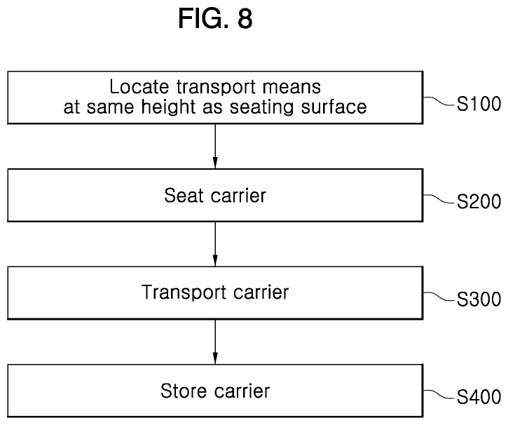

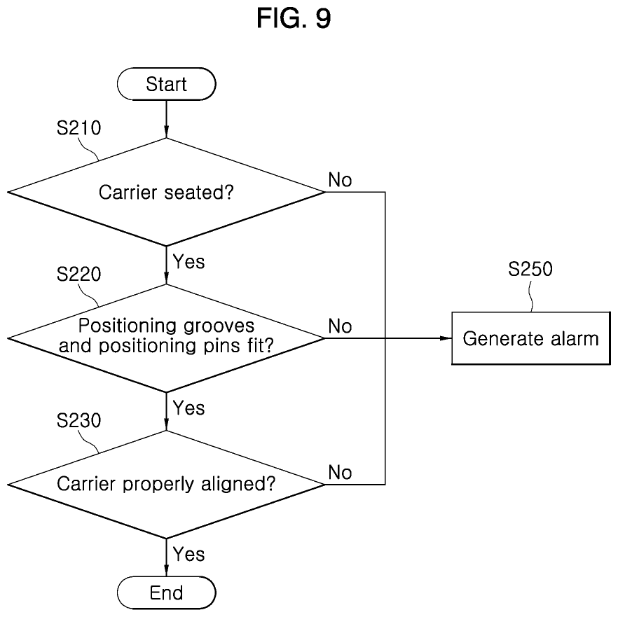

FIGS. 8 and 9 show a method for mounting a carrier according to an embodiment of the present disclosure, which is the method for mounting a carrier in the article storage system described above. FIG. 8 is a schematic flowchart of the method for mounting a carrier in the article storage system according to the embodiment of the present disclosure, and FIG. 9 is a flowchart schematically showing the second step of FIG. 8. As described above, the method for mounting a carrier in the article storage system according to the embodiment of the present disclosure may be applied to a stage included in a manual port configured to allow a user to manually place a carrier.

Referring to FIG. 8, the method for mounting a carrier in the article storage system according to the embodiment of the present disclosure may include: a first step of locating the transport module 130 at the same height as the seating surface of the stage 112 (S100); a second step of seating the carrier 10 on the seating surface of the stage 112 (S200); and a third step of transporting the carrier 10 seated on the stage 112 (S300). The transported carrier may be stored in the storage unit equipped with the plurality of shelves 120 (S400).

The first step (S100) is to put the hand 132 of the transport module 130 on standby at a position to be inserted into the passage hole formed on the seating surface of the stage 112 by lifting the transport module 130 for supporting the lower surface of the carrier 10 and transporting the carrier 10, and positioning the upper surface of the transport module 130 at the same height as the seating surface of the stage 112.

The second step (S200) is to place the carrier 10 on the stage 112 with the hand 132 inserted into the passage hole of the stage 112. As shown in FIG. 9, the second step (S200) may include: detecting the presence of a carrier (S210); detecting whether the positioning grooves 220 provided on the lower surface of the carrier 10 and the positioning pins 210 provided on the upper surface of the hand 132 of the transport module 130 are fitted (S220) to each other; detecting whether the alignment state of the carrier 10 is normal (S230); and generating an alarm (S250).

In the second step (S200), positioning may be performed as the positioning grooves 220 provided on the lower surface of the carrier and the positioning pins 210 provided on the upper surface of the hand 132 of the transport module 130 fit each other.

The step of generating an alarm (S250) may be performed in case the positioning grooves 220 provided on the lower surface of the carrier 10 and the positioning pins 210 provided on the upper surface of the hand 132 of the transport module 130 do not fit each other when the carriers 10 are seated on the stage 112, and at least one of the presence of the carrier and the alignment state of carriers is abnormal.

The second step (S200) may end when the fitting state of the positioning pins 210 and the positioning grooves 220, the presence of the carrier, and the alignment state of carriers are all normal.

As described above, the present disclosure may prevent problems such as delivery delay due to abnormal seating of an object (e.g., a carrier containing articles) in advance by immediately informing the abnormal seating of the object to an operator and inducing the normal seating of the object. Particularly, the present disclosure is cost-effective because accuracy of article placement in an article storage system may be increased without additional hardware design and manufacturing costs since it is possible to guide the seating of articles by simply changing drive logic of existing components.

Meanwhile, it is possible to normalize a seating state of articles within a shorter time since the overall seating state of articles is checked with a plurality of sensors provided on a stage and an alarm is generated in case of abnormal seating of an article.

Furthermore, by applying the article storage system of the present disclosure to a manual port where a carrier is manually seated by an operator (user), it is possible to prevent abnormal seating of articles by the operator.

The above description is merely an example of the technical idea of the present disclosure, and those skilled in the art will be able to make various modifications and variations without departing from the essential characteristics of the present disclosure. Therefore, the embodiments described in the present disclosure are not intended to limit the technical spirit of the present disclosure, but to explain, and the technical spirit of the present disclosure is not limited by these embodiments. The protection scope of the present disclosure should be interpreted by the claims below, and all technical ideas within the equivalent range should be construed as being included in the scope of the present disclosure.

What is claimed is:

1. A carrier transport facility, comprising:
a stage provided with a seating surface on which a carrier containing articles is seated;
a transport module configured to:
move up and down through a passage hole formed at the seating surface of the stage, and
transport the carrier by supporting a lower surface of the carrier; and
a controller configured to control the transport module,
wherein the transport module includes positioning pins corresponding to positioning grooves provided at the lower surface of the carrier,
wherein the positioning pins are provided at an upper surface of the transport module, and
wherein the controller controls the transport module to rise to a height of the seating surface of the stage and stand by before the carrier is seated on the seating surface of the stage, so that when the carrier is seated, the positioning grooves provided at the lower surface of the carrier and the positioning pins provided at the upper surface of the transport module are engaged with each other to attach the carrier to the transport module.

2. The carrier transport facility of claim 1,
wherein the controller comprises:
an alarm module configured to generate an alarm in case the positioning grooves provided at the lower surface of the carrier and the positioning pins provided at the upper surface of the transport module do not fit to each other when the carrier is seated on the stage.

3. The carrier transport facility of claim 2,
wherein the stage comprises:
a first sensor configured to detect a presence of the carrier; and
a second sensor configured to detect an alignment state of carriers.

4. The carrier transport facility of claim 3,
wherein the alarm module generates an alarm when it is determined that a seating state of the carrier detected by the first sensor and the second sensor is abnormal.

5. The carrier transport facility of claim 1,
wherein the transport module comprises:
a hand configured to support the lower surface of the carrier and have the positioning pins on the upper surface thereof corresponding to the positioning grooves provided at the lower surface of the carrier; and
a drive unit configured to move the hand.

6. The carrier transport facility of claim 1, further comprising:
a housing in which the transport module is accommodated; and
a rail unit configured to horizontally move the housing.

7. The carrier transport facility of claim 1,
wherein the stage is included in a manual port configured to allow a user to manually seat the carrier.

8. An article storage system, comprising:
a carrier transport unit configured to transport a carrier in which an article is stored; and
a storage unit configured to have a plurality of shelves for loading the carrier,
wherein the carrier transport unit comprises:
a load port configured to include a stage provided with a seating surface on which the carrier is seated;
a transport module configured to move up and down through a passage hole formed at the seating surface of the stage and transport the carrier by supporting a lower surface of the carrier; and
a controller configured to control the transport module,
wherein the transport module includes positioning pins corresponding to positioning grooves provided at the lower surface of the carrier,
wherein the positioning pins are provided at an upper surface of the transport module, and
wherein the controller controls the transport module to rise to a height of the seating surface of the stage and stand by before the carrier is seated on the seating surface of the stage, so that when the carrier is seated, the positioning grooves provided at the lower surface of the carrier and the positioning pins provided at the upper surface of the transport module are engaged with each other to attach the carrier to the transport module.

9. The article storage system of claim 8,
wherein the load port includes a manual port configured to allow a user to manually seat the carrier.

10. The article storage system of claim 9,
wherein the controller comprises:
an alarm module configured to generate an alarm in case the positioning grooves provided at the lower surface of the carrier and the positioning pins provided at the upper surface of the transport module do not fit to each other when the carrier is seated on the stage by the user.

11. The article storage system of claim 10,
wherein the stage comprises:
a first sensor configured to detect a presence of the carrier; and
a second sensor configured to detect an alignment state of carriers.

12. The article storage system of claim 11,
wherein the alarm module generates an alarm when it is determined that a seating state of the carrier detected by the first sensor and the second sensor is abnormal.

13. The article storage system of claim 8,
wherein the transport module comprises:
a hand configured to support the lower surface of the carrier and have the positioning pins on the upper surface thereof corresponding to the positioning grooves provided at the lower surface of the carrier; and
a drive unit configured to move the hand.

14. The article storage system of claim 8, further comprising:
a housing in which the transport module is accommodated; and
a rail unit configured to horizontally move the housing.

15. A method for seating a carrier in an article storage system, which is a method for properly seating the carrier on a stage provided with a seating surface on which the carrier containing an article is seated, the method comprising:
a first step of locating a transport module for moving up and down through a passage hole formed at the seating surface of the stage and transporting the carrier by supporting a lower surface of the carrier at a same height as the seating surface;
a second step of seating the carrier on the stage; and
a third step of transporting the carrier by the transport module.

16. The method of claim 15, wherein the second step comprises:
engaging positioning grooves provided at the lower surface of the carrier with positioning pins provided at an upper surface of the transport module, respectively.

17. The method of claim 16,
wherein the second step further comprises:
generating an alarm in case the positioning grooves provided at the lower surface of the carrier and the positioning pins provided at the upper surface of the transport module do not fit to each other when the carrier is seated on the stage.

18. The method of claim 17,
wherein the second step further comprises:
detecting a presence of the carrier; and
detecting an alignment state of carriers.

19. The method of claim 18,
wherein the second step further comprises:
generating an alarm when at least one of the presence of the carrier and the alignment state of carriers is abnormal.

20. The method of claim 15,
wherein the stage is included in a manual port configured to allow a user to manually seat the carrier.
